(19) United States
(12) Patent Application Publication
(10) Pub. No.: US 2025/0157970 A1
(43) Pub. Date: May 15, 2025

(54) FLIP CHIP STRUCTURE AND CIRCUIT BOARD THEREOF

(71) Applicant: CHIPBOND TECHNOLOGY CORPORATION, Hsinchu (TW)

(72) Inventors: Kung-Tzu Tu, Kaohsiung City (TW); Gwo-Shyan Sheu, Kaohsiung City (TW); Hsin-Hao Huang, Kaohsiung City (TW); Kuo-Liang Huang, Kaohsiung City (TW); Pei-Wen Wang, Taichung City (TW); Yu-Chen Ma, Kaohsiung City (TW)

(21) Appl. No.: 18/932,755

(22) Filed: Oct. 31, 2024

(30) Foreign Application Priority Data
Nov. 13, 2023 (TW) 112143588

(51) Int. Cl. H01L 23/00; H01L 23/498

(52) U.S. Cl. CPC H01L 24/14; H01L 23/49838; H01L 24/16; H01L 2224/1403; H01L 2224/14051; H01L 2224/14132; H01L 2224/16013; H01L 2224/16227

(57) ABSTRACT

A flip chip structure includes a circuit board and a chip. The circuit board includes first inner leads and second inner leads, each of the first inner leads has a first bonding portion, each of the second inner leads has a second bonding portion and a connecting segment. An included angle exists between the second bonding portion and the connecting segment, and an included angle exists between center lines of the first and second bonding portions. The chip includes first bumps and second bumps, and an included angle exists between center lines of the first and second bumps. Each of the first bumps is bonded to the first bonding portion, and each of the second bumps is bonded to the second bonding portion and the connecting segment to avoid bonding shift between the inner leads and the bumps or lessen bonding shift.

### CROSS-REFERENCE TO RELATED APPLICATIONS

This application claims priority to R.O.C patent application No. 112143588 filed Nov. 13, 2023, the disclosure of which is hereby incorporated by reference in its entirety.

### FIELD OF THE INVENTION

This invention relates to a flip chip structure and its circuit board, and more particularly to a flip chip structure able to avoid bonding shift between bumps on a chip and inner leads on a circuit board or diminish bonding shift level.

### BACKGROUND OF THE INVENTION

With reference to FIGS. 10 and 11, a conventional circuit board 11 includes a substrate 11a and a circuit layer 11b which is formed on the substrate 11a and covered by a protective layer (not shown). A chip-mounting area 11c defined on the substrate 11a, inner leads 11b1 and outer leads (not shown) of the circuit layer 11b are not covered by the protective layer. Bumps 12a of a chip 12 are bonded to the inner leads 11b1 arranged on the chip-mounting area 11c to obtain a flip chip structure 10.

Due to coefficients of thermal expansion (CTE) mismatch of the substrate 11a, the circuit layer 11b and the protective layer, expansion and contraction may occur in the circuit board 11 in response to temperature variation to cause bonding shift between the bumps 12a and the inner leads 11b1 on the chip-mounting area 11c. If the bonding shift is too large, the bumps 12a may be unable to be bonded to the inner leads 11b1 or the bonding area of the bumps 12a and the inner leads 11b1 may be not sufficient.

### SUMMARY OF THE INVENTION

One object of the present invention is to provide a flip chip structure and a circuit board thereof. A first bonding portion of a first inner lead and a second bonding portion of a second inner lead are arranged on a chip-mounting area defined on a circuit board in different directions. A first bump of a chip is arranged with the direction identical to the first bonding portion and bonded to the first bonding portion, and a second bump of the chip is arranged with the direction identical to the second bonding portion and bonded to the second bonding portion. Consequently, the present invention can enhance resistance of the circuit board to expansion and contraction in response to temperature variation, thereby avoiding bonding shift between the inner leads and the bumps or lowering the level of bonding shift.

A flip chip structure of the present invention includes a circuit board and a chip. The circuit board includes first inner leads and second inner leads which are both arranged on a chip-mounting area defined on the circuit board. Each of the first inner leads includes a first lead portion and a first bonding portion. Each of the second inner leads includes a second lead portion and a second bonding portion, a first connecting segment of the second lead portion is connected to the second bonding portion, and a first included angle exists between the second bonding portion and the first connecting segment. The first and second bonding portions of the first and second inner leads are alternately arranged on the chip-mounting area in a first direction. There is a first distance between the first and second bonding portions in a second direction which intersects the first direction. The first bonding portion is closer to an edge of the chip-mounting area than the second bonding portion. A second included angle exists between center lines of the first and second bonding portions. The chip includes first bumps and second bumps which are alternately arranged on an active surface of the chip in the first direction. The first bumps are closer to an edge of the active surface than the second bumps in the second direction. A third included angle exists between center lines of the first and second bumps. Each of the first bumps is bonded to the first bonding portion of one of the first inner leads, and each of the second bumps is bonded to the second bonding portion and the first connecting segment of one of the second inner leads.

A circuit board of the present invention includes first inner leads and second inner leads. Each of the first inner leads includes a first lead portion and a first bonding portion. Each of the second inner leads includes a second lead portion and a second bonding portion, a first connecting segment of the second lead portion is connected to the second bonding portion, and a first included angle exists between the second bonding portion and the first connecting segment. The second bonding portion and the first connecting segment are provided for bonding of a bump. The first and second bonding portions of the first and second inner leads are alternately arranged on a chip-mounting area defined on the circuit board. There is a first distance between the first and second bonding portions in a second direction which intersects the first direction. The first bonding portion is closer to an edge of the chip-mounting area than the second bonding portion, and a second included angle exists between center lines of the first and second bonding portions.

The first and second bonding portions of the first and second inner leads are arranged in different directions, and the first and second bumps of the chip are arranged in the directions identical to the first and second bonding portions, respectively, to be bonded to the first and second bonding portions. As a result, resistance of the circuit board to expansion and contraction in response to temperature variation can be improved to avoid bonding shift between the inner leads and the bumps or lessen bonding shift, thereby overcoming the issues of unavailable bonding of the bumps to the inner leads or insufficient bonding area between the inner leads and the bumps.

### BRIEF DESCRIPTION OF DRAWINGS

FIG. 1 is a top view diagram illustrating a flip chip structure in accordance with one embodiment of the present invention.

FIG. 2 is a top view diagram illustrating a part of a circuit board of a flip chip structure in accordance with one embodiment of the present invention.

FIG. 3 is a top view diagram illustrating a part of a circuit board of a flip chip structure in accordance with one embodiment of the present invention.

FIGS. 4A and 4B are top view diagrams illustrating a part of a circuit board of a flip chip structure in accordance with one embodiment of the present invention.

FIGS. 5A to 5D are top view diagrams illustrating a second bonding portion in accordance with different embodiments of the present invention.

FIG. 6 is a bottom view diagram illustrating a chip of a flip chip structure in accordance with one embodiment of the present invention.

FIG. 7 is a top view diagram illustrating a part of a chip of a flip chip structure in accordance with one embodiment of the present invention.

FIG. 8 is a top view diagram illustrating a part of a flip chip structure in accordance with one embodiment of the present invention.

FIG. 9 is a top view diagram illustrating a part of a flip chip structure in accordance with one embodiment of the present invention.

FIG. 10 is a cross-section view diagram illustrating a conventional flip chip structure.

FIG. 11 is a top view diagram illustrating a conventional flip chip structure.

### DETAILED DESCRIPTION OF THE INVENTION

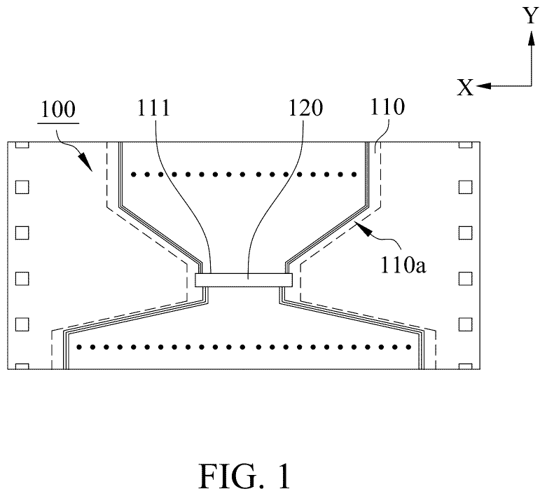

With reference to FIGS. 1, 2 and 6, a flip chip structure 100 of the present invention includes a circuit board 110 and a chip 120. In this embodiment, the circuit board 110 includes a substrate (not shown), a circuit layer 110a and a solder mask (not shown). The substrate is preferably made of flexible material, e.g. polyimide (PI) or polyethylene terephthalate (PET). The solder mask covers the circuit layer 110a but not cover a chip-mounting area 111 defined on the circuit board 110. The chip 120 is flipped and bonded to the chip-mounting area 111 via its active surface 121.

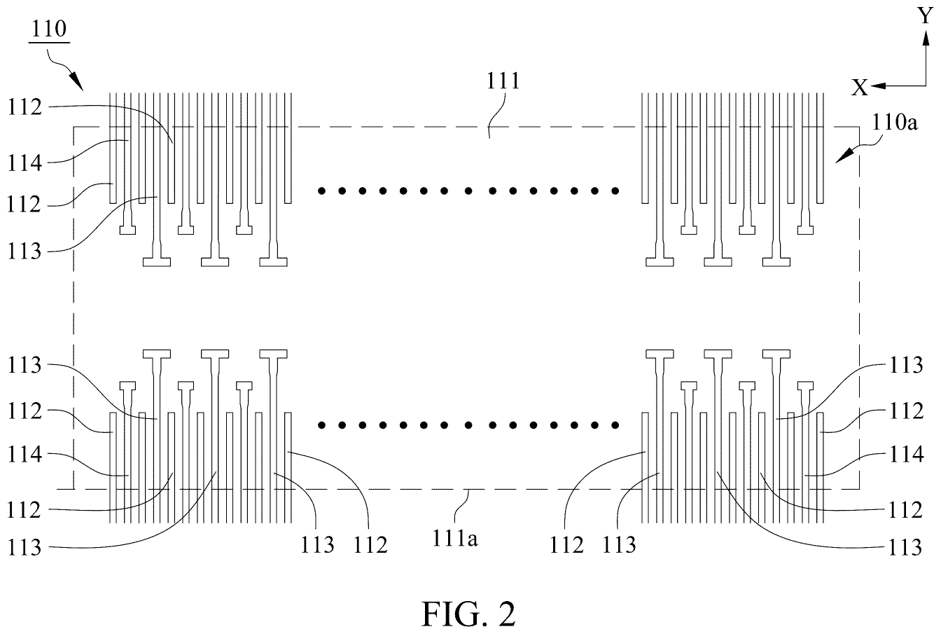

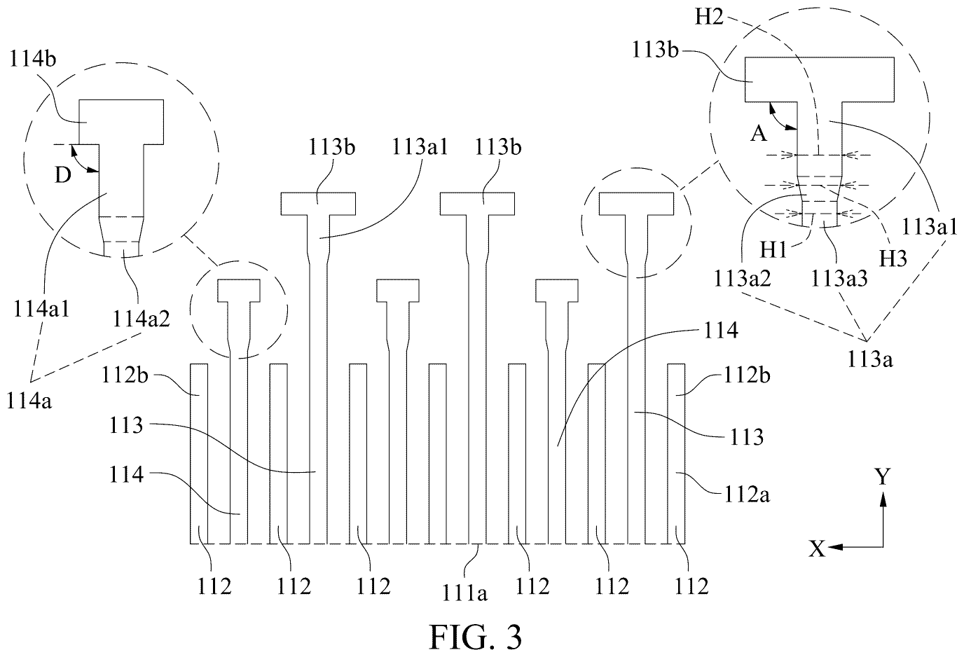

With reference to FIGS. 2 and 3, the circuit layer 110a includes first inner leads 112 and second inner leads 113 which both are arranged on the chip-mounting area 111. Each of the first inner leads 112 includes a first lead portion 112a and a first bonding portion 112b.

With reference to FIGS. 2 and 3, each of the second inner leads 113 includes a second lead portion 113a and a second bonding portion 113b. The second lead portion 113a is divided into a first connecting segment 113a1 and a first body 113a3, the first connecting segment 113a1 is connected to the second bonding portion 113b. A first included angle A exists between the first connecting segment 113a1 and the second bonding portion 113b, and a first length H1 of the first body 113a3 is less than a second length H2 of the first connecting segment 113a1. In this embodiment, the second bonding portion 113b is provided on the chip-mounting area 111 along a first direction X, the first bonding portion 112b is provided on the chip-mounting area 111 along a second direction Y which intersects the first direction X. In other words, the first bonding portion 112b and the second bonding portion 113b on the chip-mounting area 111 are extended in different directions. Preferably, the first direction X and the second direction Y are perpendicular to one another.

With reference to FIGS. 2, 3, 4A and 4B, the first and second bonding portions 112b and 113b are alternately arranged on the chip-mounting area 111 in the first direction X. A first distance S1 exists between the first and second bonding portions 112b and 113b in the second direction Y, and the first bonding portion 112b is closer to an edge 111a of the chip-mounting area 111 than the second bonding portion 113b. There is a second included angle B between a center line L1 of the first bonding portion 112b and a center line L2 of the second bonding portion 113b. In this embodiment, the center line L1 of the first bonding portion 112b is parallel to the second direction Y, and the center line L2 of the second bonding portion 113b is parallel to the first direction X.

With reference to FIG. 3, the second lead portion 113a preferably further includes a second connecting segment 113a2. The second connecting segment 113a2 is located between the first connecting segment 113a1 and the first body 113a3, and a third length H3 of the second connecting segment 113a2 is gradually reduced in the direction from the first connecting segment 113a1 toward the first body 113a3.

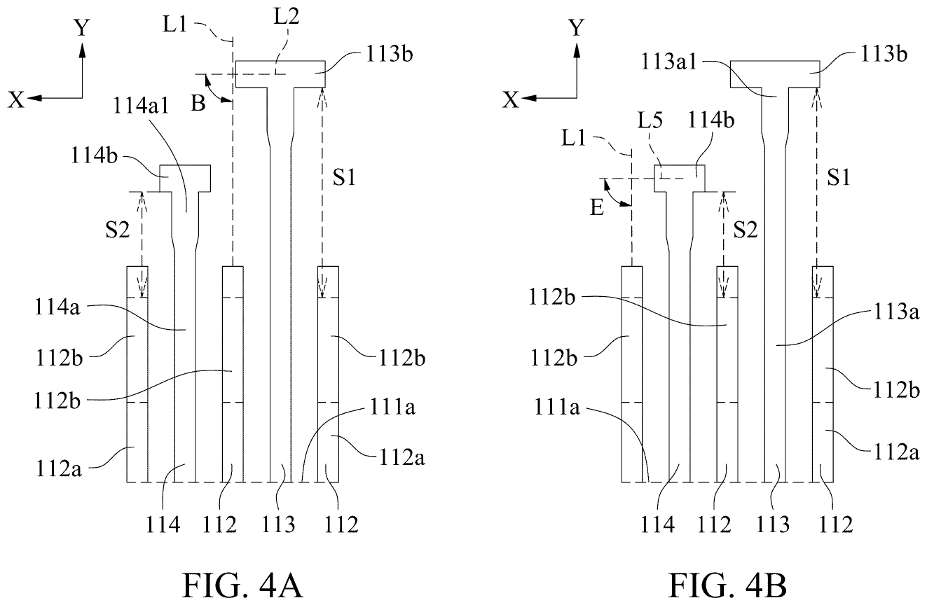

With reference to FIGS. 3, 4A and 4B, the circuit layer 110a further includes third inner leads 114 arranged on the chip-mounting area 111. Each of the third inner leads 114 includes a third lead portion 114a and a third bonding portion 114b, and the third lead portion 114a is divided into a third connecting segment 114a1 and a second body 114a2. The third connecting segment 114a1 is connected to the third bonding portion 114b, and there is a fourth included angle D between the third connecting segment 114a1 and the third bonding portion 114b.

With reference to FIGS. 3, 4A and 4B, the first, second and third bonding portions 112b, 113b and 114b are alternately arranged on the chip-mounting area 111 along the first direction X. A second distance S2 from the first bonding portion 112b to the third bonding portion 114b is less than the first distance S1 from the first bonding portion 112b to the second bonding portion 113b in the second direction Y. The first bonding portion 112b is closer to the edge 111a of the chip-mounting area 111 than the third bonding portion 114b, and the third bonding portion 114b is closer to the edge 111a of the chip-mounting area 111 than the second bonding portion 113b. There is a fifth included angle E between the center line L1 of the first bonding portion 112b and a center line L5 of the third bonding portion 114b. And in this embodiment, the center line L5 of the third bonding portion 114b is parallel to the second direction Y.

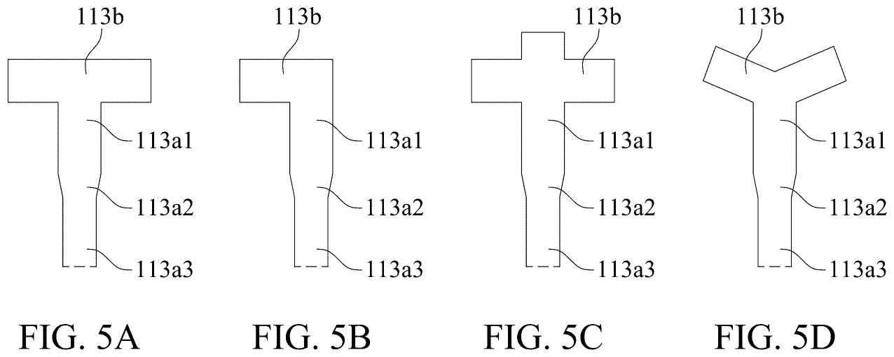

As shown in FIGS. 5A to 5D, the second bonding portion 113b can be inverted L-shape, T-shape, Y-shape or cross-shape. Similarly, the third bonding portion 114b also can be inverted L-shape, T-shape, Y-shape or cross-shape.

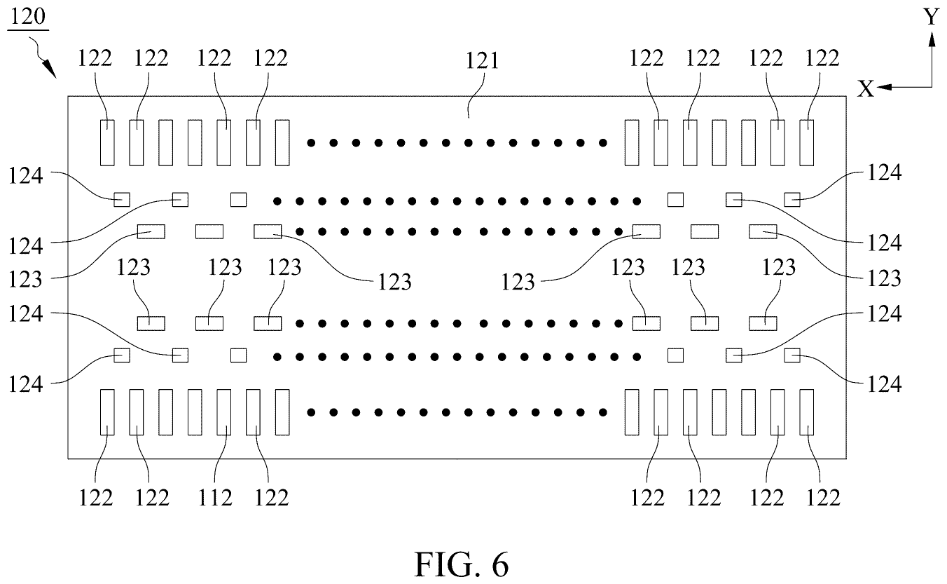

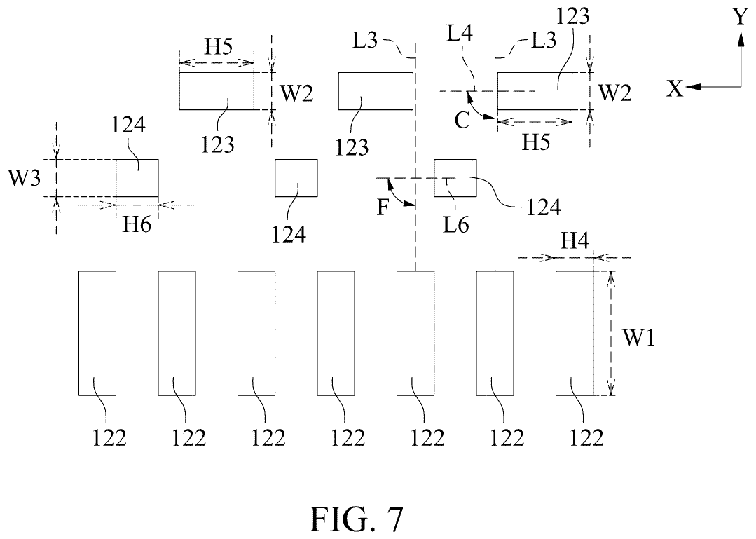

With reference to FIGS. 6 and 7, the chip 120 includes first bumps 122 and second bumps 123, and it further includes third bumps 124 in this embodiment. The first, second and third bumps 122, 123 and 124 are alternately arranged on the active surface 121 of the chip 120 in the first direction X. And in the second direction Y, the first bumps 122 are closer to an edge 121a of the active surface 121 than the second and third bumps 123 and 124, and the third bumps 124 are closer to the edge 121a of the active surface 121 than the second bumps 123. A third included angle C exists between a center line L3 of the first bumps 122 and a center line L4 of the second bumps 123, and the third included angle C is substantially equal to the second included angle B between the center line L1 of the first bonding portion 112b and the center line L2 of the second bonding portion 113b. In this embodiment, the center line L3 of the first bumps 122 is parallel to the second direction Y, and the center line L4 of the second bumps 123 is parallel to the first direction X.

With reference to FIG. 7, along the direction of the center line L4 of the second bumps 123, the first bumps 122 have a fourth length H4 and the second bumps 123 have a fifth length H5 which is greater than the fourth length H4. There is a sixth included angle F between the center line L3 of the first bumps 122 and a center line L6 of the third bumps 124, and the center line L6 of the third bumps 124 is parallel to the first direction X in this embodiment. Along the direction of the center line L6 of the third bumps 124, the third bumps 124 have a sixth length H6 which is greater than the fourth length H4 of the first bumps 122. The sixth length H6 of the third bumps 124 is less than the fifth length H5 of the third bumps 124 in this embodiment. The arrangement directions of the first, second and third bumps 122, 123 and 124 are identical to that of the first, second and third bonding portions 112b, 113b and 114b, respectively.

With reference to FIG. 7, the first bumps 122 have a first width W1, the second bumps 123 have a second width W2 and the third bumps 124 have a third width W3 in the direction of the center line L3 of the first bumps 122, the second width W2 and the third width W3 are less than the first width W1. The fourth length H4 of the first bumps 122 is less than the first width W1 of the first bumps 122, the fifth length H5 of the second bumps 123 is greater than the second width W2 of the second bumps 123 and less than or equal to the first width W1 of the first bumps 122, and the sixth length H6 of the third bumps 124 is greater than the third width W3 of the third bumps 124. Preferably, the fifth length H5 of the second bumps 123 and the sixth length H6 of the third bumps 124 are designed to be less than the first width W1 of the first bumps 122 in order to lower metal usage in the second and third bumps 123 and 124.

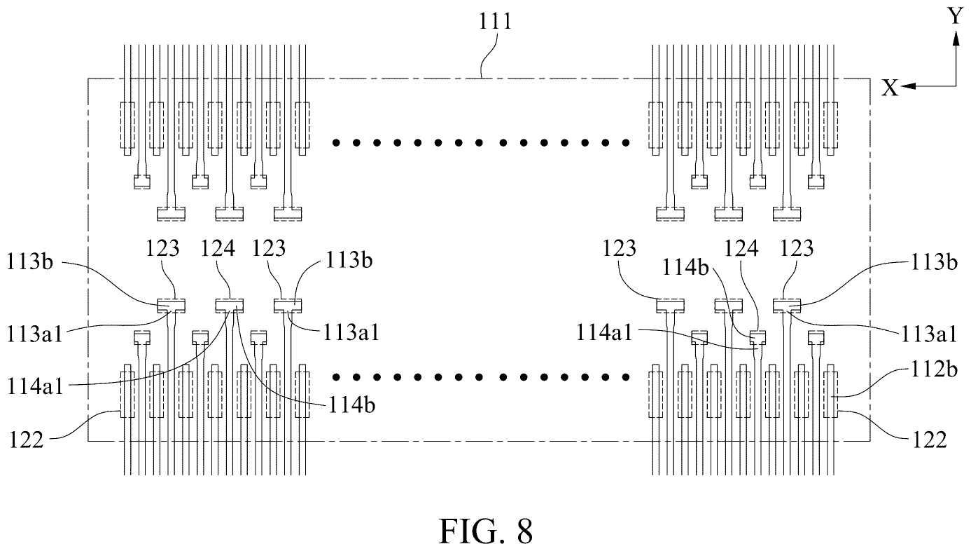

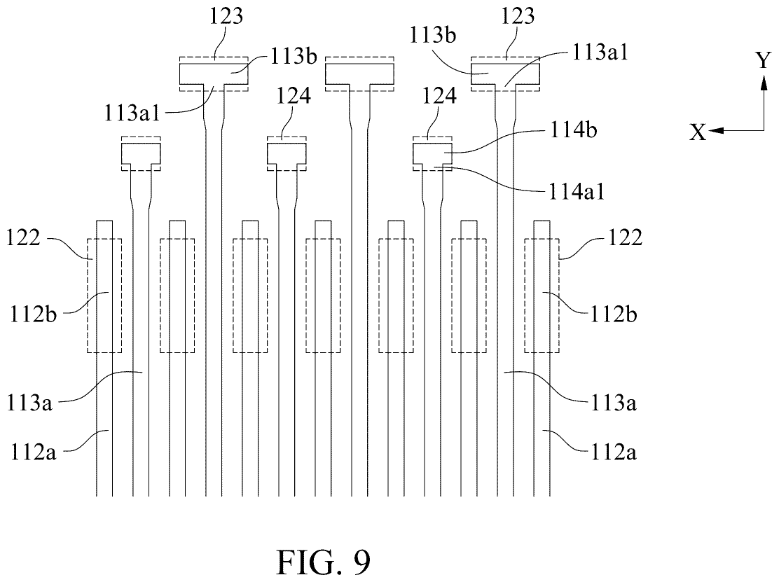

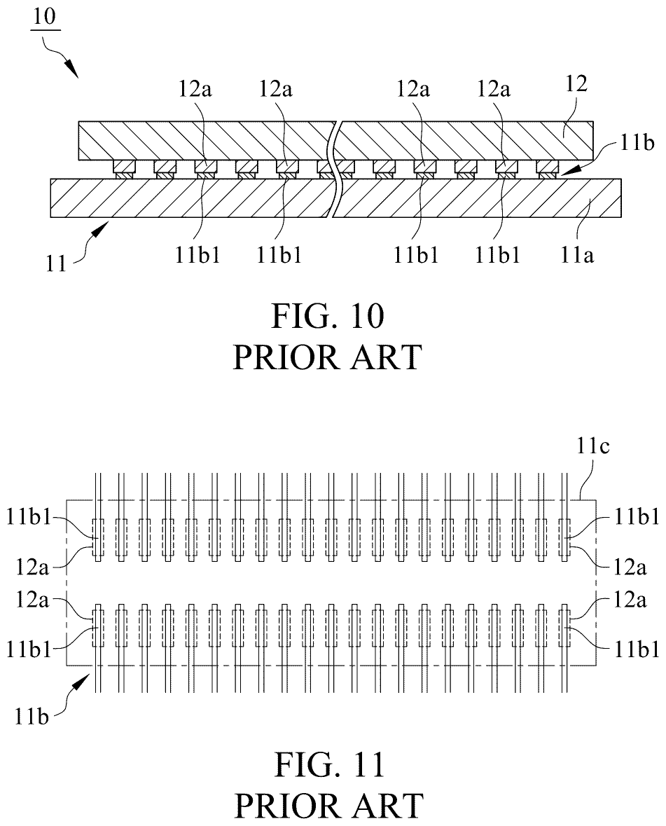

With reference to FIGS. 8 and 9, the first bumps 122 are bonded to the first bonding portions 112b of the first inner leads 112, the second bumps 123 are bonded to the second bonding portions 113b and the first connecting segments 113a1 of the second inner leads 113, and the third bumps 124 are bonded to the third bonding portions 114b and the third connecting segment 114a1 of the third inner leads 114. The first, second and third bonding portions 112b, 113b and 114b are arranged in different directions on the chip-mounting area 111, and the arrangement directions of the first, second and third bumps 122, 123 and 124 are identical to that of the first, second and third bonding portions 112b, 113b and 114b, respectively. As a result, it can enhance resistance of the circuit board 110 to expansion and contraction in response to temperature variation in the first direction X and the second direction Y, thereby avoiding bonding shift between the inner leads and the bumps or lessening bonding shift.

With reference to FIGS. 3, 7 and 9, the second width W2 of the second bumps 123 is less than the first width W1 of the first bumps 122, the fifth length H5 of the second bumps 123 is greater than the fourth length H4 of the first bumps 122 and not greater than the first width W1 of the first bumps 122, so metal usage of the second bumps 123 can be reduced. Furthermore, due to the second length H2 of the first connecting segment 113a1 is greater than the first length H1 of the first body 113a3, it is able to increase the bonding area of the second bump 123 and the second inner lead 113 while the second bump 123 is bonded to the second bonding portion 113b and the first connecting segment 113a1, prevent the second bump 123 from separating from the second inner lead 113 and improve resistance of the circuit board 110 to expansion and contraction in response to temperature variation.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A flip chip structure comprising:
a circuit board including a plurality of first inner leads and a plurality of second inner leads, the plurality of first and second inner leads are arranged on a chip-mounting area defined on the circuit board, each of the plurality of first inner leads includes a first lead portion and a first bonding portion, each of the plurality of second inner leads includes a second lead portion and a second bonding portion, wherein a first connecting segment of the second lead portion is connected to the second bonding portion, there is a first included angle between the second bonding portion and the first connecting segment, the first and second bonding portions of the plurality of first and second inner leads are alternately arranged on the chip-mounting area in a first direction, there is a first distance between the first and second bonding portions in a second direction intersecting the first direction, the first bonding portion is closer to an edge of the chip-mounting area than the second bonding portion, and there is a second included angle between center lines of the first and second bonding portions; and
a chip including a plurality of first bumps and a plurality of second bumps, the plurality of first and second bumps are alternately arranged on an active surface of the chip in the first direction, the plurality of first bumps are closer to an edge of the active surface than the plurality of second bumps in the second direction, wherein there is a third included angle between center lines of the plurality of first and second bumps, each of the plurality of first bumps is bonded to the first bonding portion of one of the plurality of first inner leads, and each of the plurality of second bumps is bonded to the second bonding portion and the first connecting segment of one of the plurality of second inner leads.

2. The flip chip structure in accordance with claim 1, wherein the second lead portion further includes a first body, a first length of the first body is less than a second length of the first connecting segment.

3. The flip chip structure in accordance with claim 2, wherein the second lead portion further includes a second connecting segment located between the first connecting segment and the first body, a third length of the second connecting segment is gradually reduced in a direction from the first connecting segment toward the first body.

4. The flip chip structure in accordance with claim 1, wherein a first width of each of the plurality of first bumps is greater than a second width of each of the plurality of second bumps in a direction of the center line of each of the plurality of first bumps, a fourth length of each of the plurality of first bumps is less than a fifth length of each of the plurality of second bumps in a direction of the center line of each of the plurality of second bumps, the first width of each of the plurality of first bumps is greater than the fourth length of each of the plurality of first bumps, the second width of each of the plurality of second bumps is less than the fifth length of each of the plurality of second bumps, the fifth length of each of the plurality of second bumps is less than or equal to the first width of each of the plurality of first bumps.

5. The flip chip structure in accordance with claim 1, wherein the first bonding portion is arranged on the chip-mounting area along the second direction and the center line of the first bonding portion is parallel to the second direction, the second bonding portion is arranged on the chip-mounting area along the first direction and the center line of the second bonding portion is parallel to the first direction.

6. The flip chip structure in accordance with claim 4, wherein the circuit board further includes a plurality of third inner leads arranged on the chip-mounting area, each of the plurality of third inner leads includes a third lead portion and a third bonding portion, a third connecting segment of the third lead portion is connected to the third bonding portion, there is a fourth included angle between the third bonding portion and the third connecting segment, the first, second and third bonding portions of the plurality of first, second and third inner leads are alternately arranged on the chip-mounting area in the first direction, there is a second distance between the first and third bonding portions in the second direction, the second distance is less than the first distance between the first and second bonding portions, the first bonding portion is closer to the edge of the chip-mounting area than the third bonding portion, there is a fifth included angle between the center line of the first bonding portion and a center line of the third bonding portion, the chip further includes a plurality of third bumps, the plurality of first, second and third bumps are alternately arranged on the active surface of the chip in the first direction, the plurality of first bumps are closer to the edge of the active surface than the plurality of third bumps, there is a sixth included angle between the center line of each of the plurality of first bumps and a center line of each of the plurality of third bumps, each of the plurality of third bumps is bonded to the third bonding portion and the third connecting segment of one of the plurality of third inner leads.

7. The flip chip structure in accordance with claim 6, wherein the first width of each of the plurality of first bumps is greater than a third width of each of the plurality of third bumps in a direction of the center line of each of the plurality of first bumps, a sixth length of each of the plurality of third bumps is greater than the fourth length of each of the plurality of first bumps in a direction of the center line of each of the plurality of third bumps.

8. The flip chip structure in accordance with claim 7, wherein the first bonding portion is arranged on the chip-mounting area along the second direction and the center lines of each of the plurality of first bumps and the first bonding portion of each of the plurality first inner leads are parallel to the second direction, the second and third bonding portions are arranged on the chip-mounting area along the first direction and the center lines of each of the plurality of second and third bumps, the second bonding portion of each of the plurality of second inner leads and the third bonding portion of each of the plurality of third inner leads are parallel to the first direction.

9. The flip chip structure in accordance with claim 1, wherein the second bonding portion is inverted L-shape, T-shape, Y-shape or cross-shape.

10. A circuit board comprising:
a plurality of first inner leads each including a first lead portion and a first bonding portion; and
a plurality of second inner leads each including a second lead portion and a second bonding portion, wherein a first connecting segment of the second lead portion is connected to the second bonding portion, there is a first included angle between the second bonding portion and the first connecting segment, the second bonding portion and the first connecting segment of the second lead portion are configured to bond with a bump, the first and second bonding portions of the plurality of first and second inner leads are alternately arranged on a chip-mounting area defined on the circuit board in a first direction, there is a first distance between the first and second bonding portions in a second direction intersecting the first direction, the first bonding portion is closer to an edge of the chip-mounting area than the second bonding portion, and there is a second included angle between center lines of the first and second bonding portions.

11. The circuit board in accordance with claim 10, wherein the second lead portion further includes a first body, a first length of the first body is less than a second length of the first connecting segment.

12. The circuit board in accordance with claim 11, wherein the second lead portion further includes a second connecting segment located between the first connecting segment and the first body, a third length of the second connecting segment is gradually reduced in a direction from the first connecting segment toward the first body.

13. The circuit board in accordance with claim 10, wherein the first bonding portion is arranged on the chip-mounting area along the second direction and the center line of the first bonding portion is parallel to the second direction, the second bonding portion is arranged on the chip-mounting area along the first direction and the center line of the second bonding portion is parallel to the first direction.

14. The circuit board in accordance with claim 10 further comprising a plurality of third inner leads arranged on the chip-mounting area, wherein each of the plurality of third inner leads includes a third lead portion and a third bonding portion, a third connecting segment of the third lead portion is connected to the third bonding portion, there is a fourth included angle between the third bonding portion and the third connecting segment, the first, second and third bonding portions of the plurality of first, second and third inner leads are alternately arranged on the chip-mounting area in the first direction, there is a second distance between the first and third bonding portions in the second direction, the second distance is less than the first distance between the first and second bonding portions, the first bonding portion is closer to the edge of the chip-mounting area than the third bonding portion, and there is a fifth included angle between the center line of the first bonding portion and a center line of the third bonding portion.

15. The circuit board in accordance with claim 14, wherein the first bonding portion is arranged on the chip-mounting area along the second direction and the center line of the first bonding portion is parallel to the second direction, the second and third bonding portions are arranged on the chip-mounting area along the first direction and the center lines of the second and third bonding portions are parallel to the first direction.

16. The circuit board in accordance with claim 10, wherein the second bonding portion is inverted L-shape, T-shape, Y-shape or cross-shape.
